(19) United States
(12) Patent Application Publication
(10) Pub. No.: US 2024/0035168 A1
(43) Pub. Date: Feb. 1, 2024

(54) SUBSTRATE PROCESSING APPARATUS AND SUBSTRATE PROCESSING METHOD

(71) Applicant: Tokyo Electron Limited, Tokyo (JP)

(72) Inventor: Hironobu HYAKUTAKE, Koshi City (JP)

(21) Appl. No.: 18/354,705

(22) Filed: Jul. 19, 2023

(30) Foreign Application Priority Data
Jul. 27, 2022 (JP) 2022-119411

(51) Int. Cl. C23F 1/08; C23F 1/26; C23F 1/46

(52) U.S. Cl. CPC C23F 1/08; C23F 1/26; C23F 1/46

(57) ABSTRACT

A substrate processing apparatus includes: a processing tank configured to store a processing liquid for processing a substrate; a circulation path through which the processing liquid is taken out from the processing tank and is returned to the processing tank; a substrate holder configured to hold the substrate; a lifter configured to raise and lower the substrate holder between an immersion position inside the processing tank and a standby position above the processing tank; and a controller configured to control the lifter, wherein the processing liquid is a mixed liquid obtained by mixing a first component and a second component and generates a heat of mixing, and the controller is configured to perform a control to immerse the substrate in the mixed liquid before a temperature of the mixed liquid rises due to the heat of mixing and reaches a peak temperature.

### CROSS-REFERENCE TO RELATED APPLICATION

This application is based upon and claims the benefit of priority from Japanese Patent Application No. 2022-119411, filed on Jul. 27, 2022, the entire contents of which are incorporated herein by reference.

### TECHNICAL FIELD

The present disclosure relates to a substrate processing apparatus and a substrate processing method.

### BACKGROUND

The substrate processing apparatus disclosed in Patent Document 1 includes: a processing tank that stores a processing liquid; a circulation path that circulates the processing liquid in the processing tank; a substrate holder that holds a substrate; and a lifter that raises and lowers the substrate holder between an immersion position in the processing tank and a standby position above the processing tank. The processing liquid is a mixture of a sulfuric acid and a hydrogen peroxide.

### PRIOR ART DOCUMENTS

### Patent Documents

Patent Document 1: Japanese Patent Laid-open Publication No. 2011-114305

### SUMMARY

According to one embodiment of the present disclosure, a substrate processing apparatus includes: a processing tank configured to store a processing liquid for processing a substrate; a circulation path through which the processing liquid is taken out from the processing tank and is returned to the processing tank; a substrate holder configured to hold the substrate; a lifter configured to raise and lower the substrate holder between an immersion position inside the processing tank and a standby position above the processing tank; and a controller configured to control the lifter, wherein the processing liquid is a mixed liquid obtained by mixing a first component and a second component and generates a heat of mixing, and the controller is configured to perform a control to immerse the substrate in the mixed liquid before a temperature of the mixed liquid rises due to the heat of mixing and reaches a peak temperature.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a front cross-sectional view illustrating a substrate processing apparatus according to an embodiment.

FIG. 2 is a side cross-sectional view illustrating an example of an inner tank and a substrate holder in FIG. 1.

FIG. 3 is a flowchart illustrating a substrate processing method according to an embodiment.

FIG. 4 is a timing chart illustrating an example of the substrate processing method.

FIG. 5 is a diagram illustrating an example of time-dependent changes in temperature, H₂O₂ concentration, and H₂SO₄ concentration.

FIG. 6 is a diagram illustrating an example of a relationship between a temperature and an etching rate.

FIG. 7 is a diagram illustrating an example of a relationship between the H₂O₂ concentration and the etching rate.

### DETAILED DESCRIPTION

Hereinafter, embodiments of the present disclosure will be described with reference to the drawings. In each drawing, the same or corresponding components may be denoted by the same reference numerals, and a description thereof may be omitted. In the present specification, the X-axis direction, the Y-axis direction, and the Z-axis direction are perpendicular to each other. The X-axis direction and Y-axis direction are horizontal directions, and the Z-axis direction is a vertical direction. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In the related art, a batch-type apparatus and a single-wafer-type apparatus are known as substrate processing apparatuses. In the batch-type apparatus, a plurality of substrates are processed at once by immersing the substrates in a processing liquid at the same time. On the other hand, in the single-wafer-type apparatus, a substrate is horizontally held and rotated while a processing liquid is dropped onto an upper surface of the substrate. The technique of the present disclosure relates to a batch-type technique. The batch-type technique is suitable for long-term processing compared to a single-wafer-type technique.

A mixed liquid obtained by mixing a first component and a second component may be used as the processing liquid. Here, the mixed liquid may contain a third component. The mixed liquid generates heat of mixing. The heat of mixing is reaction heat generated by mixing a plurality of types of components. For example, when a sulfuric acid and a hydrogen peroxide solution (H₂O₂+H₂O) are mixed with each other, heat of dilution of the sulfuric acid, heat of hydration of the sulfuric acid and water, or heat of reaction of the sulfuric acid and the hydrogen peroxide is generated. Multiple kinds of heat of mixing may occur in a stepwise manner depending on a temperature.

The higher the temperature, the more likely the exothermic reaction is to proceed, and the temperature of the mixed liquid may rise rapidly. As a result, the temperature of the mixed liquid may overshoot a target temperature. Thereafter, when the substrates start to be immersed in the mixed liquid after the temperature of the mixed liquid is stabilized at the target temperature, the waiting time until the start of immersion becomes longer. As a result, the processing capacity of the substrate processing apparatus (the number of substrates processed per unit time) is reduced.

In addition, when the temperature of the mixed liquid overshoots the target temperature, thermal decomposition is promoted. For example, the hydrogen peroxide decomposes into water and oxygen at a high temperature. The concentration of the hydrogen peroxide drops significantly below a target concentration due to the thermal decomposition. Even if the mixed liquid is replenished with the hydrogen peroxide thereafter, it is difficult to restore the concentration of the hydrogen peroxide in the mixed liquid to the target concentration.

As will be described in detail later, in the technique of the present disclosure, the substrates are immersed in the mixed liquid before the temperature of the mixed liquid rises due to the heat of mixing and reaches a peak temperature (maximum temperature). As a result, the substrates can be processed before the concentration of the thermally decomposing component is significantly reduced, and the substrates can be processed efficiently. Further, the waiting time until the start of immersion can be shortened, and the substrates can be processed efficiently.

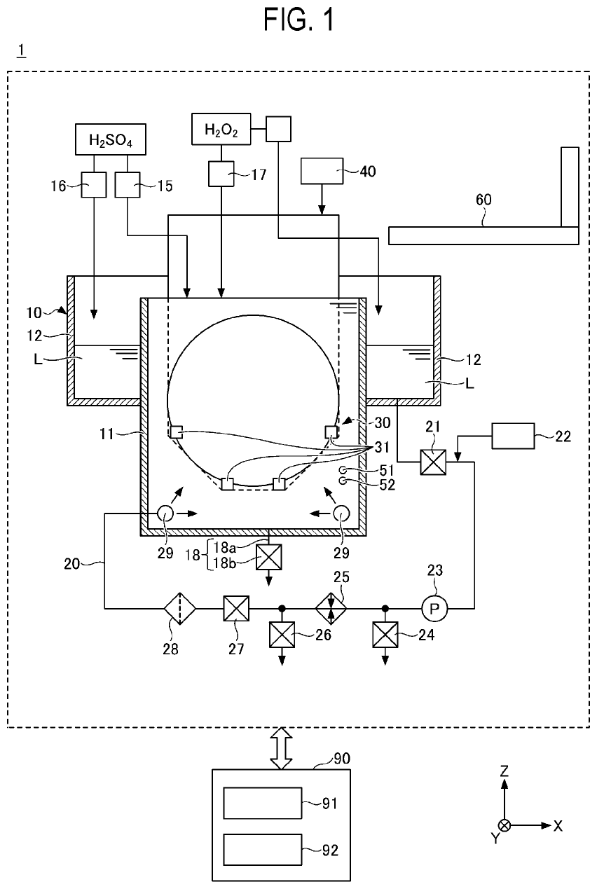

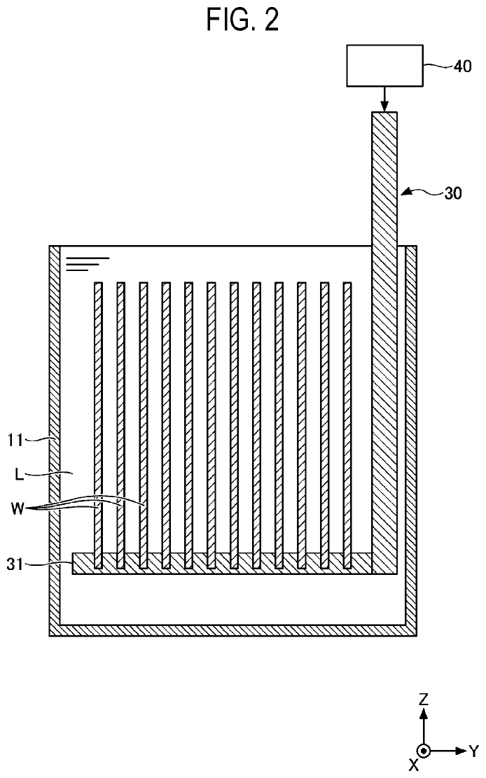

First, a substrate processing apparatus 1 according to an embodiment will be described with reference to FIGS. 1 and 2. The substrate processing apparatus 1 includes, for example, a processing tank 10, a first component supplier 15, a second component supplier 17, a discharger 18, a circulation path 20, a substrate holder 30, a lifter 40, and a controller 90.

The processing tank 10 stores a processing liquid L for processing substrates W. The processing tank 10 includes, for example, an inner tank 11 and an outer tank 12. The inner tank 11 stores the processing liquid L. The plurality of substrates W are immersed in the processing liquid L stored in the inner tank 11. The outer tank 12 collects the processing liquid L overflowing from the inner tank 11.

The processing liquid L is a mixed liquid obtained by mixing a first component and a second component, and is a mixed liquid that generates heat of mixing. For example, the first component is a sulfuric acid and the second component is a hydrogen peroxide. The processing liquid L may contain a third component. The third component is, for example, water. The processing liquid L is, for example, an aqueous solution containing the sulfuric acid and the hydrogen peroxide (so-called SPM: sulfuric acid-hydrogen peroxide mixture).

The processing liquid L is used as, for example, an etching liquid. The etchant removes desired films formed on the substrates W. For example, the SPM removes resist films, polysilicon films, amorphous silicon films, or metal films. The metal films are, for example, tungsten films.

The SPM used to remove the metal films has a relatively high target concentration of hydrogen peroxide and a relatively high target temperature. A target value of the mixing ratio (mass ratio) of hydrogen peroxide and sulfuric acid (H₂O₂/H₂SO₄) may be greater than ¼. The target temperature may be 125 degrees C. to 170 degrees C., more specifically 130 degrees C. to 170 degrees C.

The higher the target concentration of hydrogen peroxide, the more likely the heat of mixing is generated. In addition, the higher the target temperature, the more likely the heat of mixing is generated. Therefore, the technique of the present disclosure is particularly effective when using SPM to remove the metal films.

The first component supplier 15 supplies the first component constituting the processing liquid L to the processing tank 10. The first component supplier 15 is, for example, a sulfuric acid supplier. The sulfuric acid may be supplied to the processing tank 10 in the form of an aqueous solution. A supply destination of the sulfuric acid is the inner tank 11. The first component supplier 15 includes, for example, an opening/closing valve, a flow controller, and a flow meter (not illustrated).

The second component supplier 17 supplies the second component constituting the processing liquid L to the processing tank 10. The second component supplier 17 is, for example, a hydrogen peroxide supplier. The hydrogen peroxide may be supplied to the processing tank 10 in the form of an aqueous solution. A supply destination of the hydrogen peroxide is the inner tank 11. The second component supplier 17 includes, for example, an opening/closing valve, a flow controller, and a flow meter (not illustrated).

The discharger 18 discharges the processing liquid L stored in the processing tank 10. For example, the discharger 18 discharges the processing liquid L stored in the inner tank 11. The discharger 18 includes a discharge path 18a and an opening/closing valve 18b. One end of the discharge path 18a is connected to the inner tank 11. The opening/closing valve 18b opens and closes the discharge path 18a under the control of the controller 90.

The circulation path 20 takes out the processing liquid L from the processing tank 10 and returns the same to the processing tank 10. The processing liquid L may be circulated, and the mixing of a plurality of components constituting the processing liquid L may be promoted. For example, the circulation path 20 takes out the processing liquid L from the outer tank 12 and returns the same to the inner tank 11. The circulation path 20 has an upstream end connected to the outer tank 12 and a downstream end connected to a nozzle 29 provided inside the inner tank 11.

In the middle of the circulation path 20, for example, from the upstream side to the downstream side, a first opening/closing valve 21, a cooling gas source 22, a pump 23, a first cooling gas discharger 24, a heater 25, a second cooling gas discharger 26, a second opening/closing valve 27, and a filter 28 are provided in this order. In addition, the types and order of devices provided in the middle of the circulation path 20 are not particularly limited.

The cooling gas source 22 supplies a cooling gas to the circulation path 20 while the first opening/closing valve 21 closes the circulation path 20 in the vicinity of the outer tank 12. A nitrogen gas or a dry air is used as the cooling gas. The cooling gas discharges the processing liquid L remaining in the circulation path 20 to the outside of the circulation path 20 from the first cooling gas discharger 24 and the second cooling gas discharger 26. As a result, the circulation path 20 can be cooled down.

While the cooling gas source 22 supplies the cooling gas to the circulation path 20, the controller 90 causes the pump 23 to run idle. In addition, while the cooling gas source 22 supplies the cooling gas to the circulation path 20, the second opening/closing valve 27 closes the circulation path 20 to prevent the filter 28 from drying. The second opening/closing valve is provided on the upstream side of the filter 28.

The cooling gas source 22 supplies a cooling gas at room temperature to the circulation path 20, but may supply a cooling gas at a temperature lower than the room temperature to the circulation path 20. The circulation path 20 can be efficiently cooled down. The cooling gas source 22 may have a cooling machine that cools the cooling gas at the room temperature to a temperature lower than the room temperature. The cooling gas source 22 is an example of a cooler.

Instead of (or in addition to) the cooling gas source 22, a cooling liquid supplier 16 may be used as a cooler. The cooling liquid supplier 16 supplies a cooling liquid to the circulation path 20 via the processing tank 10 (e.g., the outer tank 12). As the cooling liquid, for example, sulfuric acid, which is the first component, is used. The cooling liquid discharges the processing liquid L remaining in the circulation path 20 to the inner tank 11. As a result, the circulation path 20 can be cooled down.

The controller 90 operates the pump 23 to supply the cooling liquid to the circulation path 20. In addition, the controller 90 opens the first opening/closing valve 21 and the second opening/closing valve 27 to allow the cooling liquid to pass through the same. After passing through the circulation path 20 and being discharged to the inner tank 11, the cooling liquid is discharged to the outside of the inner tank 11 from the discharger 18.

The cooling liquid supplier 16 supplies a cooling liquid at the room temperature to the circulation path 20, but may supply a cooling liquid at a temperature lower than the room temperature to the circulation path 20. The circulation path 20 can be efficiently cooled down. The cooling liquid supplier 16 may have a cooling machine that cools the cooling liquid at the room temperature to a temperature lower than the room temperature.

The substrate holder 30 holds substrates W as illustrated, for example, in FIG. 2. For example, the substrate holder 30 arranges a plurality of substrates W side by side in a Y-axis direction and holds each substrate W vertically. The substrate holder 30 includes a plurality of (e.g., four) holding arms 31. Each holding arm 31 is provided along the Y-axis direction and has a plurality of grooves at intervals in the Y-axis direction. The individual substrates W are held by the grooves in the holding arms 31.

The lifter 40 raises and lowers the substrate holder 30 between an immersion position inside the processing tank 10 and a standby position above the processing tank 10. The lifter 40 includes, for example, a motor (not illustrated) and a ball screw configured to convert a rotational motion of the motor into a linear motion of the substrate holder 30. In addition, the lifter 40 may move the substrate holder 30 in a horizontal direction.

The controller 90 is, for example, a computer, and includes a calculator 91 such as a central processing unit (CPU) and a storage 92 such as a memory. The storage 92 stores programs for controlling various processes executed in the substrate processing apparatus 1. The controller 90 controls an operation of the substrate processing apparatus 1 by causing the calculator 91 to execute the programs stored in the storage 92.

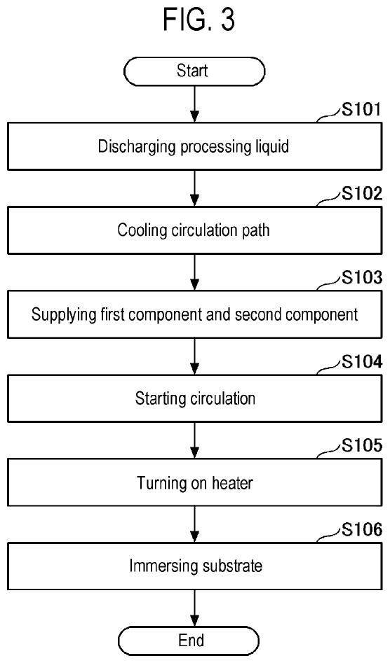

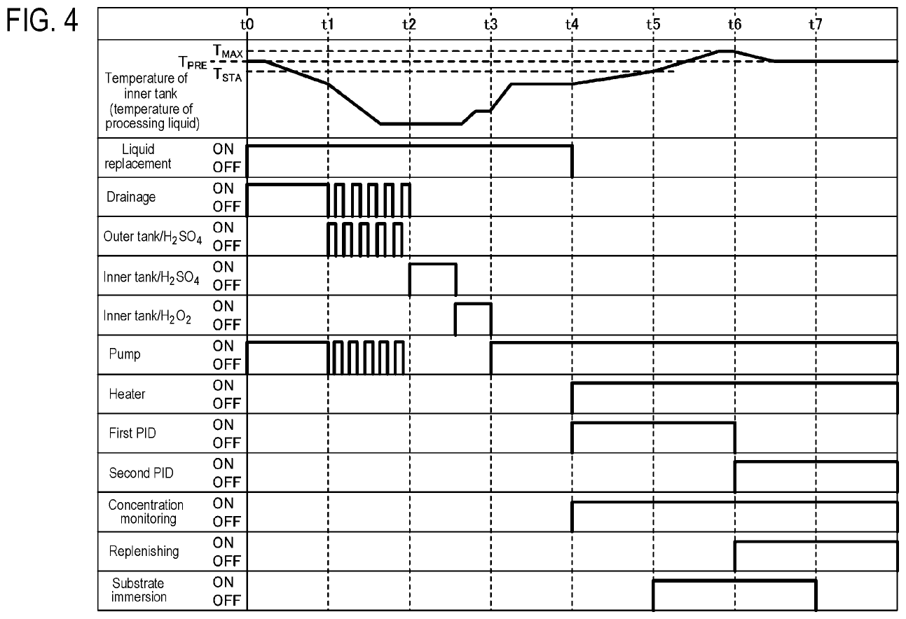

Next, a substrate processing method according to an embodiment will be described with reference to FIGS. 3 and 4. The substrate processing method includes, for example, steps 5101 to S106 illustrated in FIG. 3. Steps S101 to S106 are performed under the control of the controller 90. In addition, the substrate processing method may not include all of steps S101 to S106, and may include processes other than steps S101 to S106.

Processing after step S101 illustrated in FIG. 3 is started when the preparation of a new batch is completed. One batch includes a plurality (e.g., 25, 50, or 100) of substrates W. The processing after step 5101 is performed for each batch. The processing liquid L is replaced for each batch.

First, from time t0 to time t1, the discharger 18 discharges the processing liquid L from the inner tank 11 to empty the inner tank 11 (step S101). During this time, the pump 23 sends the processing liquid L from the outer tank 12 to the inner tank 11 via the circulation path 20 to empty the outer tank 12. By step S101, the interiors of the inner tank 11 and the outer tank 12 become empty. However, since the processing liquid L remains in the circulation path 20, the circulation path 20 remains at a high temperature.

Subsequently, the circulation path 20 is cooled down from time t1 to time t2 (step S102). Specifically, for example, supplying, by the cooling liquid supplier 16, a cooling liquid to the circulation path 20 via the outer tank 12 and discharging, by the discharger 18, the cooling liquid from the inner tank 11 are alternately and repeatedly performed. Instead of (or in addition to) the cooling liquid supplier 16, the cooling gas source 22 may be used to cool down the circulation path 20. In any case, by cooling down the circulation path 20, residual heat can be removed, and promotion of an exothermic reaction due to the residual heat can be prevented.

Subsequently, from time t2 to time t3, the first component supplier 15 supplies the sulfuric acid at room temperature to the inner tank 11, and the second component supplier 17 supplies the hydrogen peroxide at room temperature to the inner tank 11 (step S103). The hydrogen peroxide is supplied in the form of an aqueous solution. As the supply of the hydrogen peroxide solution progresses, the mixture of the hydrogen peroxide solution and the sulfuric acid generates heat of mixing, and a temperature T of the processing liquid L rises.

Next, at time t3, the pump 23 starts circulation of the processing liquid L (step S104). The circulation promotes the mixing of the hydrogen peroxide solution and the sulfuric acid, and the heat of mixing further increases the temperature T of the processing liquid L. As illustrated in FIG. 4, the temperature T of the processing liquid L rises to, for example, around 110 degrees C. and is temporarily stabilized.

Next, at time t4, the heater 25 starts heating of the processing liquid L (step S105). The heater 25 is provided in the circulation path 20, but may be provided in the processing tank 10. The heater 25 is an example of a heating part that heats the processing liquid L. After time t4, the temperature T of the processing liquid L rises again, and heat of mixing is generated again.

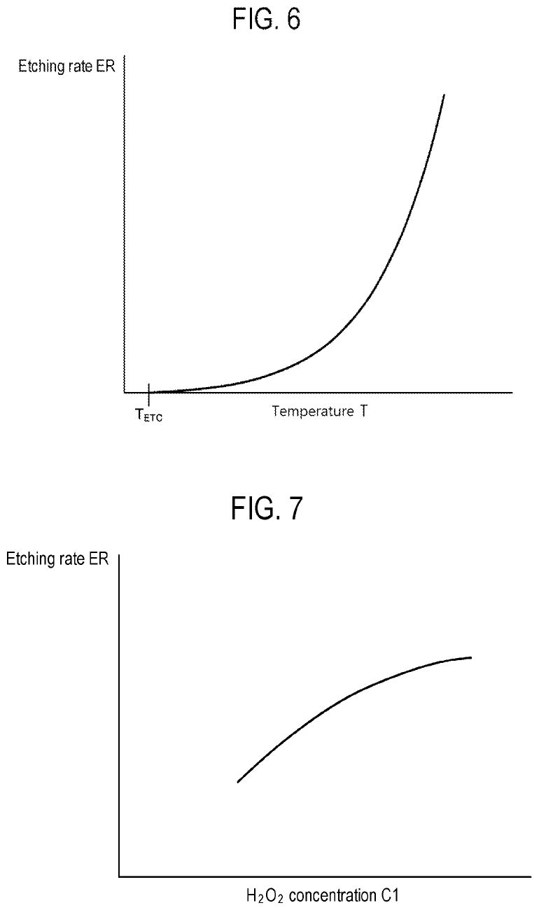

Next, at time t5, when the temperature T of the processing liquid L reaches an immersion start temperature T_{STA} (e.g., 130 degrees C.), the lifter 40 lowers the substrate holder 30 from the standby position to the immersion position, so that the substrates W are immersed in the processing liquid L (step S106). The immersion start temperature T_{STA} may be set higher than an etching start temperature T_{ETC} to be described later (see FIG. 6), but may be set lower than the etching start temperature T_{ETC}.

After time t5, the temperature T of the processing liquid L overshoots a target temperature T_{PRE} (e.g., 140 degrees C.) due to the heat of mixing. The target temperature T_{PRE} is higher than the immersion start temperature T_{STA}. The temperature T of the processing liquid L exceeds the target temperature T_{PRE} and then reaches a peak temperature T_{MAX} (e.g., 160 degrees C.). The peak temperature T_{MAX} is higher than the target temperature T_{PRE}.

The peak temperature T_{MAX} is controlled not to exceed a threshold. The threshold is determined based on, for example, a heat-resistant temperature of the processing tank 10. When the peak temperature T_{MAX} exceeds the threshold, the controller 90 may reduce the amount of the hydrogen peroxide solution supplied to the processing tank 10 from time t2 to time t3 to reduce the generated amount of heat of mixing. The temperature T starts to drop after reaching the peak temperature T_{MAX}.

Next, at time t6, the controller 90 detects that the temperature T reaches the peak temperature T_{MAX} by detecting that the temperature T starts to decrease from the peak temperature T_{MAX}. The temperature T is detected by a temperature detector 51 (see FIG. 1). The temperature detector 51 is provided in the processing tank 10, but may be provided in the circulation path 20. The temperature detector 51 transmits a signal indicating the detection result to the controller 90. The controller 90 detects the temperature T reaching the peak temperature T_{MAX}, for example, from a slope of the temperature T or the like.

After time t6, the controller 90 controls the heater 25 with a setting different from that before time t6. That is, the controller 90 controls the heater 25 with different settings before and after the temperature T of the processing liquid L reaches the peak temperature T_{MAX}. The heater 25 may be appropriately controlled in a period in which a large amount of heat of mixing is generated and a period in which a small amount of heat of mixing is generated.

For example, the controller 90 feedback-controls the heater 25 by using different transfer functions before and after the temperature T of the processing liquid L reaches the peak temperature T_{MAX} (before and after time t6). When the feedback control is PID control or PI control, the transfer functions include at least a proportional gain Kp and an integral gain Ki. The proportional gain Kp before time t6 is set larger than the proportional gain Kp after time t6. The integral gain Ki before time t6 is set smaller than the integral gain Ki after time t6.

In addition, the controller 90 may perform a constant-current control of the heater 25 with different current values, for example, before and after the temperature T of the processing liquid L reaches the peak temperature T_{MAX} (before and after time t6). The supply current to the heater 25 before time t6 may be set smaller than the supply current to the heater 25 after time t6. This is because the temperature is positively adjusted by using the heater 25 after time t6.

In the period from the start of mixing of the sulfuric acid and the hydrogen peroxide until the temperature T of the processing liquid L reaches the peak temperature T_{MAX}, a total heat quantity of mixing is greater than a total heat quantity of the heater 25. On the other hand, the total heat quantity of the mixing is smaller than the total heat quantity of the heater 25 in the period from the time when the temperature T of the processing liquid L reaches the peak temperature T_{MAX} to the time when the substrates W are completely immersed.

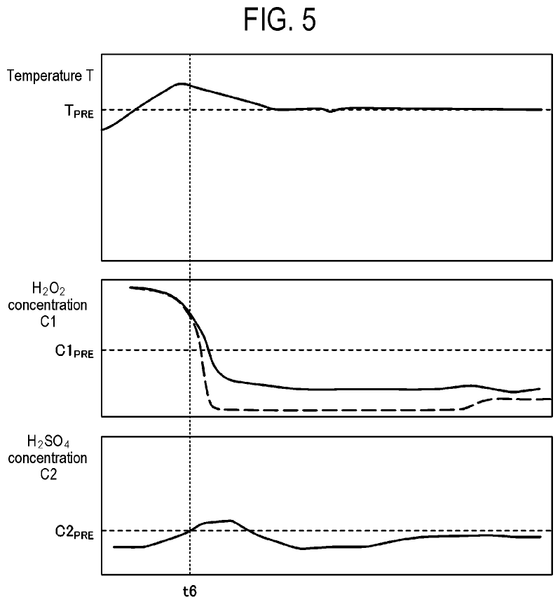

After time t6, the second component supplier 17 may supply the hydrogen peroxide to the processing tank 10. When the temperature T of the processing liquid L overshoots the target temperature T_{PRE}, thermal decomposition of the hydrogen peroxide is promoted. When the hydrogen peroxide is not replenished, the concentration of the hydrogen peroxide is significantly lower than a target concentration C1_{PRE}, as indicated by the dashed line in FIG. 5.

Therefore, after time t6, the second component supplier 17 may supply the hydrogen peroxide to the processing tank 10 to suppress a decrease in the concentration of the hydrogen peroxide. After time t6, the generation of heat of mixing subsides. When the hydrogen peroxide is replenished after the generation of heat of mixing subsides, excessive temperature rise of the processing liquid L can be suppressed.

Further, in FIG. 5, C2_{PRE} is a target concentration of the sulfuric acid.

Next, at time t7, the lifter 40 raises the substrate holder 30 from the immersion position to the standby position, and pulls up the substrates W out of the processing liquid L. Thus, the immersion of the substrates W in the processing liquid L is terminated. The immersion time is set in advance by experiments or the like, and is set in advance based on, for example, a film thickness and an etching rate of an object target.

The controller 90 may correct the immersion time for each batch so that the etching amount is within an allowable range. For example, the controller 90 acquires at least one of a temperature profile and a concentration profile of the processing liquid L, and corrects the immersion time based on data thus acquired. This is because the etching rate depends on the temperature T and the hydrogen peroxide concentration C1.

As illustrated in FIG. 6, etching starts when the temperature T exceeds the etching start temperature T_{ETC}. The higher the temperature T of the processing liquid L, the faster the etching rate ER. A relational expression between the etching rate ER and the temperature T is obtained in advance by experiments or the like. The controller 90 may correct the immersion time based on the relational expression between the etching rate ER and the temperature T and the temperature profile. In addition, after the temperature T exceeds the etching start temperature T_{ETC}, the controller 90 may integrate a difference between T and T_{ETC} (T−T_{ETC}) and may correct the immersion time based on a value thus integrated.

As illustrated in FIG. 7, the etching rate ER also depends on the hydrogen peroxide concentration C1. The higher the hydrogen peroxide concentration C1, the faster the etching rate ER. A relational expression between the etching rate ER and the hydrogen peroxide concentration C1 is obtained in advance by experiments or the like. The controller 90 may correct the immersion time based on the relational expression between the etching rate ER and the hydrogen peroxide concentration C1 and the profile of the hydrogen peroxide concentration C1. The relational expression between the etching rate ER and the hydrogen peroxide concentration C1 may be prepared for each temperature T.

The hydrogen peroxide concentration C1 is detected by a concentration detector 52 (FIG. 1). The concentration detector 52 is provided in the processing tank 10, but may be provided in the circulation path 20. The concentration detector 52 transmits a signal indicating the detection result to the controller 90. The concentration detector 52 may detect a sulfuric acid concentration C2. The hydrogen peroxide concentration C1 and the sulfuric acid concentration C2 may be detected by separate concentration detectors 52, respectively.

As described above, according to the present embodiment, the substrates W are immersed in the processing liquid L before the temperature T of the processing liquid L rises due to the heat of mixing and reaches the peak temperature T_{MAX}. As a result, the substrates W can be processed before the concentration of the thermally decomposing component (e.g., hydrogen peroxide) drops significantly, so the substrates W can be processed efficiently. Further, the waiting time until the start of immersion can be shortened, so the substrate W can be processed efficiently.

The substrate processing apparatus 1 may include a predictor configured to predict the temperature profile in the process in which the temperature T of the processing liquid L rises toward the peak temperature T_{MAX}. The predictor may be a part of the controller 90. The predictor predicts a temperature profile of a current batch based on, for example, temperature profiles of past batches. The temperature profiles vary little between batches.

The controller 90 performs control to transmit, to a transfer device 60 (see FIG. 1), a command to transfer the substrates W to the substrate holder 30 based on the prediction result of the predictor before the temperature T of the processing liquid L reaches the peak temperature T_{MAX}. As a result, the substrates W can be immersed in the processing liquid L before the temperature T of the processing liquid L rises due to the heat of mixing and reaches the peak temperature T_{MAX}.

In the present embodiment, when the temperature T of the processing liquid L reaches the immersion start temperature T_{STA} (e.g., 130 degrees C.) at time t5, the immersion of the substrates W is started, but the technique of the present disclosure is not limited thereto. For example, the immersion of the substrates W may be started after the circulation of the processing liquid L is started (time t3) and before the heating by the heater 25 is started (time t4).

Before the start of heating by the heater 25 (time t4), the sulfuric acid and the hydrogen peroxide solution are uniformly mixed, and the temperature T of the processing liquid L is temporarily stabilized. The immersion of the substrates W may begin while the temperature T is stable. In this case, it is easier to manage the time of starting the immersion of the substrates W compared to the case where the immersion of the substrates W is started while the temperature T is rising.

In addition, before the start of heating by the heater 25 (time t4), the temperature T is lower than the etching start temperature T_{ETC}, and etching does not substantially start. The etching amount can be managed by an elapsed time from the time when the temperature T reaches the etching start temperature T_{ETC}, or the like. This facilities the management of the etching amount. The immersion of the substrates W may be started while the temperature T is stable below the etching start temperature T_{ETC}.

According to an aspect of the present disclosure, substrates can be efficiently processed when the substrates are immersed in a mixed liquid that generates heat of mixing.

Although the embodiments of the substrate processing apparatus and the substrate processing method according to the present disclosure have been described above, the present disclosure is not limited to the above-described embodiments or the like. Various changes, modifications, substitutions, additions, deletions, and combinations may be made within the scope of the claims. Of course, these also fall within the technical scope of the present disclosure.

What is claimed is:

1. A substrate processing apparatus comprising:
a processing tank configured to store a processing liquid for processing a substrate;
a circulation path through which the processing liquid is taken out from the processing tank and is returned to the processing tank;
a substrate holder configured to hold the substrate;
a lifter configured to raise and lower the substrate holder between an immersion position inside the processing tank and a standby position above the processing tank; and
a controller configured to control the lifter,
wherein the processing liquid is a mixed liquid obtained by mixing a first component and a second component and generates a heat of mixing, and
wherein the controller is configured to perform a control to immerse the substrate in the mixed liquid before a temperature of the mixed liquid rises due to the heat of mixing and reaches a peak temperature.

2. The substrate processing apparatus of claim 1, further comprising:
a heater configured to heat the mixed liquid,
wherein the controller is further configured to control the heater with different settings before and after the temperature of the mixed liquid reaches the peak temperature.

3. The substrate processing apparatus of claim 2, wherein the controller is further configured to feedback-control the heater by using different transfer functions before and after the temperature of the mixed liquid reaches the peak temperature.

4. The substrate processing apparatus of claim 2, wherein the controller is further configured to perform a constant-current control on the heater with different current values before and after the temperature of the mixed liquid reaches the peak temperature.

5. The substrate processing apparatus of claim 2, wherein, in a period from a start of the mixing of the first component and the second component until the temperature of the mixed liquid reaches the peak temperature, a total heat quantity of the heat of mixing is larger than a total heat quantity of the heater, and in a period from a time when the temperature of the mixed liquid reaches the peak temperature to a time when the substrate is completely immersed, the total heat quantity of the heat of mixing is smaller than the total heat quantity of the heater.

6. The substrate processing apparatus of claim 1, further comprising:
a predictor configured to predict a temperature profile in a process in which the temperature of the mixed liquid rises toward the peak temperature; and
a transfer device configured to transfer the substrate,
wherein the controller is further configured to perform a control to transmit, to the transfer device, a command to transfer the substrate to the substrate holder based on a prediction result obtained by the predictor before the temperature of the mixed liquid reaches the peak temperature.

7. The substrate processing apparatus of claim 1, wherein the first component is a sulfuric acid, and the second component is a hydrogen peroxide.

8. The substrate processing apparatus of claim 7, further comprising:
a sulfuric acid supplier configured to supply the sulfuric acid to the processing tank; and
a hydrogen peroxide supplier configured to supply the hydrogen peroxide to the processing tank,
wherein the controller is further configured to perform a control to replenish the hydrogen peroxide to the processing tank after the temperature of the mixed liquid reaches the peak temperature and before the immersion of the substrate in the mixed liquid is terminated.

9. The substrate processing apparatus of claim 1, further comprising:
a temperature detector configured to detect the temperature of the mixed liquid; and
a concentration detector configured to detect a concentration of the first component or the second component in the mixed liquid,
wherein the controller is further configured to acquire at least one of a temperature profile or a concentration profile of the mixed liquid, and to perform control to correct an immersion time of the substrate in the mixed liquid based on acquired data.

10. The substrate processing apparatus of claim 1, further comprising:
a discharger configured to discharge the mixed liquid from the processing tank; and
a cooler configured to supply a cooling liquid or a cooling gas to the circulation path,
wherein the controller is further configured to perform a control to supply the cooling liquid or the cooling gas to the circulation path after discharging the mixed liquid from the processing tank.

11. The substrate processing apparatus of claim 2, further comprising:
a predictor configured to predict a temperature profile in a process in which the temperature of the mixed liquid rises toward the peak temperature; and
a transfer device configured to transfer the substrate,
wherein the controller is further configured to perform a control to transmit, to the transfer device, a command to transfer the substrate to the substrate holder based on a prediction result obtained by the predictor before the temperature of the mixed liquid reaches the peak temperature.

12. The substrate processing apparatus of claim 2, wherein the first component is a sulfuric acid, and the second component is a hydrogen peroxide.

13. A substrate processing method comprising:
storing a processing liquid for processing a substrate in a processing tank;
taking out the processing liquid from the processing tank into a circulation path and returning the processing liquid from the circulation path to the processing tank; and
immersing the substrate in the processing liquid stored in the processing tank,
wherein the processing liquid is a mixed liquid obtained by mixing a first component and a second component and generates a heat of mixing, and
wherein the substrate processing method further comprises immersing the substrate in the mixed liquid before a temperature of the mixed liquid rises due to the heat of mixing and reaches a peak temperature.

14. The substrate processing method of claim 13, further comprising:
heating the mixed liquid by a heater; and
controlling the heater with different settings before and after the temperature of the mixed liquid reaches the peak temperature.

15. The substrate processing method of claim 13, further comprising:
predicting a temperature profile of a process in which the temperature of the mixed liquid rises toward the peak temperature; and
transmitting, to a transfer device, a command to transfer the substrate based on a predicted result obtained in the predicting before the temperature of the mixed liquid reaches the peak temperature.

16. The substrate processing method of claim 13, wherein the first component is a sulfuric acid, and the second component is a hydrogen peroxide.

17. The substrate processing method of claim 16, further comprising:
replenishing the hydrogen peroxide to the processing tank after the temperature of the mixed liquid reaches the peak temperature and before the immersing of the substrate in the mixed liquid is terminated.

18. The substrate processing method of claim 13, further comprising:
acquiring at least one of a temperature profile or a concentration profile of the processing liquid; and
correcting an immersion time of the substrate in the mixed liquid based on acquired data.

19. The substrate processing method of claim 13, wherein a process of discharging the mixed liquid from the processing tank and a process of storing the mixed liquid in the processing tank are performed for each substrate batch.

20. The substrate processing method of claim 13, further comprising:
cooling down the circulation path after discharging the mixed liquid from the processing tank and before storing the mixed liquid in the processing tank again.
